(19) United States
(12) Patent Application Publication
(10) Pub. No.: US 2025/0080098 A1
(43) Pub. Date: Mar. 6, 2025

(54) ON-RESISTANCE ENHANCEMENT FOR POWER CONVERTER

(71) Applicant: TEXAS INSTRUMENTS INCORPORATED, Dallas, TX (US)

(72) Inventors: Michael Lueders, Freising (DE); Jerrin James, Bangalore (IN)

(21) Appl. No.: 18/664,044

(22) Filed: May 14, 2024

Related U.S. Application Data
(60) Provisional application No. 63/580,776, filed on Sep. 6, 2023.

(51) Int. Cl. H03K 17/06; H03K 17/10

(52) U.S. Cl. CPC H03K 17/063; H03K 17/102; H03K 2217/0063; H03K 2217/0072

(57) ABSTRACT

An apparatus includes a first transistor having a first transistor control terminal and coupled between a power terminal and a switching terminal. The apparatus further includes a second transistor having a second transistor control terminal and coupled between the switching terminal and a ground terminal. The apparatus further includes a first switch coupled between the power terminal and the second transistor control terminal, the first switch having a first switch control terminal; The apparatus further includes a second switch coupled between the second control terminal and the ground terminal, the second switch having a second switch control terminal. The apparatus also includes a controller having a control input, a first control output, and a second control output, the control input coupled to the second transistor control terminal, the first control output coupled to the first switch control terminal, and the second control output coupled to the second switch control terminal.

### RELATED APPLICATION

This application claims priority to U.S. Provisional Application No. 63/580,776, filed Sep. 6, 2023, entitled “On-Resistance Enhancement for Switch-Mode Converter,” which is hereby incorporated by reference.

### BACKGROUND

Conduction loss is one of the significant contributors to power losses for power converters. One source of conduction loss is the on resistance of the switches in a switch-mode power converter.

### SUMMARY

In one example, an apparatus comprises: a first transistor, a second transistor, a first switch, a second switch, and a controller. The first transistor is coupled between a power terminal and a switching terminal, the first transistor having a first transistor control terminal. The second transistor is coupled between the switching terminal and a ground terminal, the second transistor having a second transistor control terminal. The first switch is coupled between the power terminal and the second transistor control terminal, the first switch having a first switch control terminal. The second switch is coupled between the second transistor control terminal and the ground terminal, the second switch having a second switch control terminal. The controller has a control input, a first control output, and a second control output, the control input coupled to the second transistor control terminal, the first control output coupled to the first switch control terminal, and the second control output coupled to the second switch control terminal.

In one example, an apparatus comprises a capacitor, a first switch, a second switch, and a controller. The capacitor has a first terminal and a second terminal, the second terminal coupled to a ground terminal. The first switch is coupled between the first terminal and a transistor control terminal, the first switch having a first switch control terminal. The second switch is coupled between the transistor control terminal and the ground terminal, the second switch having a second switch control terminal. The controller has a control input, a first control output, and a second control output, the control input coupled to the transistor control terminal, the first control output coupled to the first switch control terminal, and the second control output coupled to the second switch control terminal.

In one example, a method comprises receiving a control signal, and responsive to the control signal having a first state: disconnecting a current terminal of a first transistor from a power terminal; connecting a control terminal of a second transistor to the power terminal; and responsive to a voltage of the control terminal exceeding a threshold, disconnecting the control terminal from the power terminal. The method further comprises responsive to the control signal having a second state: connecting the current terminal to the power terminal; and connecting the control terminal to a ground terminal.

### BRIEF DESCRIPTION OF THE DRAWINGS

FIG. 1 is a schematic diagram of an example of a switch-mode power converter.

FIG. 2 are graphs illustrating example operations of the power converter of FIG. 1.

FIG. 3 is a schematic diagram of examples of internal components of the power converter of FIG. 1.

FIGS. 4 and 5 are graphs illustrating example operations of the power converter of FIG. 1.

FIG. 6 is a schematic diagram of examples of internal components of the power converter of FIG. 1.

FIG. 7 are graphs illustrating example operations of the power converter of FIG. 1.

FIGS. 8, 9A, 9B, and 9C are schematic diagrams of examples of internal components of the power converters of FIG. 1.

FIGS. 10, 11A, 11B, and 11C are graphs illustrating example operations of the power converter of FIG. 1.

FIG. 12 are graphs illustrating examples of efficiency across load of power converters.

FIG. 13 is a flowchart of an example of a method of controlling a switch of a power converter.

### DETAILED DESCRIPTION

The same reference numbers or other reference designators are used in the drawings to designate the same or similar (either by function and/or structure) features.

As described above, conduction loss is one of the significant contributors to power losses for power converters. One source of conduction loss is the ON-resistance (RDS_ON or R_{ON}) of the switches in a switch-mode power converter. A switch is implemented using one or more transistors, such a field effect transistor (FET), and the RDS_ON is a function of width (W) to length (L) ratio (W/L ratio) of the FET. A bigger W/L ratio leads to a smaller RDS_ON and gate-source voltage (V_GS or V_{GS}) of the FET, while a bigger V_GS voltage results in a smaller RDS_ON of the FET.

One way to reduce the conduction loss of the converter is to increase the W/L ratio of the FET of the converter, i.e., to increase the size of the FET, since increasing the W/L ratio of the FET reduces the RDS_ON, thereby reducing the conduction loss of the converter. Increasing the size of the FET, however, can increase parasitic capacitance of the FET, which can increase other loss (e.g., gate charge loss) of the converter and reduce the efficiency of the converter. The area of the converter also increases. Another factor that affects the RDS_ON of the FET, gate-source voltage (V_GS or V_{GS}) of the FET, may be limited by the input voltage (Vᵢₙ) of the converter. Various techniques are described below that can reduce the limit on the gate-source voltage imposed by the input voltage, which can reduce the RDS_ON of the FET and conduction loss and increase the overall efficiency of the power converter.

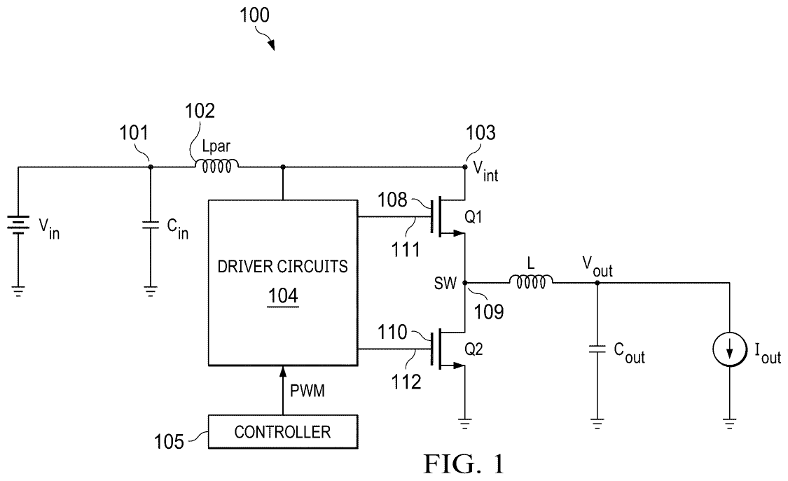

FIG. 1 is a schematic diagram of an example switch-mode power converter 100. As shown in the example of FIG. 1, the converter 100 has an external power node/terminal 101 to receive an external supply voltage Vᵢₙ from an external power source and an input/internal power node/terminal 103. The external power source connects to and charges an external input decoupling capacitor Cᵢₙ of the power converter 100. There is also a parasitic inductance 102 (also labelled Lpar) between the external power terminal 101 and the input power terminal 103. The parasitic inductance 102 can represent the inductance of various metal interconnects between the external power terminal 101 and input power terminal 103. For example, input/internal power node/terminal 103 can be on a semiconductor die of an integrated circuit, and parasitic inductance 102 can represent the inductance of, for example, bond wires between the semiconductor die and the package substrate of the integrated circuit, and solder balls/pins/pillars of the package substrate.

Power converter 100 also includes driver circuits 104, a controller 105, a high side FET 108 (also labelled Q1), and a low side FET 110 (also labelled Q2) on the semiconductor die. High side FET 108 and low side FET 110 are coupled between the input power terminal 103 and a ground terminal. Each of the high side FET 108 and the low side FET 110 also has a current terminal, which can be either a source or a drain of the corresponding FET. The high side FET 108 is coupled between the input power terminal 103 and a switching terminal 109 (also labelled SW), and the low side FET 110 is coupled between the switching terminal 109 and a ground terminal. Driver circuits 104 have outputs coupled to gate/control terminal/node 111 of the high side FET 108 and gate/control terminal/node 112 of the low side FET 110. Driver circuits 104 have an input coupled to an output of the controller 105. The driver circuits 104 can receive a control signal, such as a pulse width modulation (PWM) signal, from controller 105, and set the voltage of the gate/control terminal/node 111 of the high side FET 108 and the voltage of the gate/control terminal/node 112 of the high side FET 108 based on a state of the control signal. The power converter 100 also includes an inductor L and a capacitor Cout coupled between the load (represented by a current source Iₒᵤₜ) and the switching terminal 109.

The controller 105 can provide a PWM signal to the driver circuits 104, which turn on/off the high side FET 108 and the low side FET 110 based on the PWM signal. When the high side FET 108 is turned on and the low side FET 110 is turned off, the switching node/terminal 109 is connected to the input power terminal 103 to charge inductor L. When the high side FET 108 is turned off and the low side FET 110 is turned on, the switching node/terminal 109 is connected to the ground, the inductor L discharges. Through controlling the duty cycle of the PWM signal and/or other characteristics (e.g., frequency) of the control signal to the driver circuits 104, controller 105 can set the voltage Vout. The capacitor Cout can also be discharged to supply the current to Iout when the switching node/terminal 109 is disconnected from the input power terminal 103.

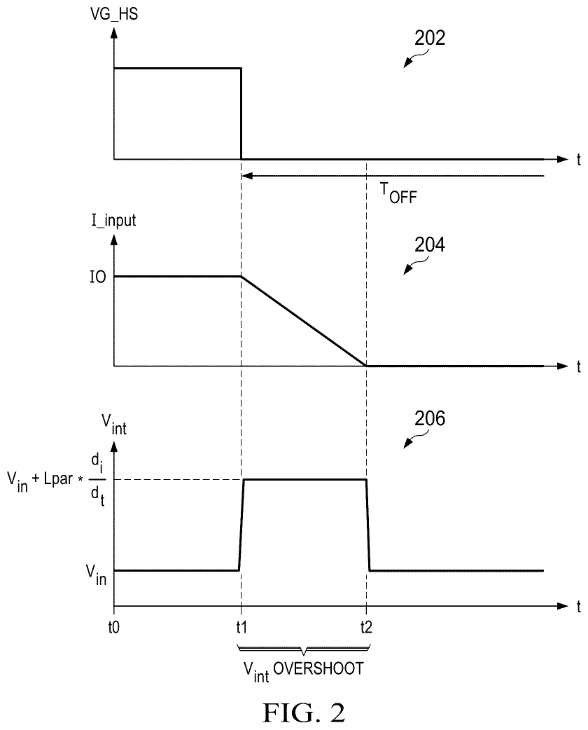

FIG. 2 include graphs depicts an example of waveforms illustrating examples of operations of the power converter 100. Graph 202 illustrates an example variation of the gate voltage of the high side FET 108 (VG_HS) with time. Graph 204 illustrates an example variation of the input current (supplied by an external source that provides the external voltage Vᵢₙ) with time. Graph 206 illustrates an example variation of the internal node voltage Vᵢₙₜ at an input/internal power node/terminal 103 with respect to time.

Between times t0 and t1, the high side FET 108 gate voltage is at a high state, and the high side FET 108 is turned on. The SW node voltage is at Vᵢₙ. Since the high side FET 108 is ON, the external voltage source supplies a current I0 through the Lpar 102 and the high side FET 108. Thus, Lpar 102 would be carrying current and storing energy.

The high side FET 108 is turned off at time t1, which starts the turn off interval (Toff in FIG. 2) of the high side FET 108 and the turn on interval of the low side FET 110. As a result of the high side FET 108 being turned off, the current through Lpar decreases from I0 at a rate dᵢ/dₜ between times t1 and t2. The reduction of the current through Lpar causes a voltage overshoot of the voltage at input power terminal 103 (Vᵢₙₜ) from Vᵢₙ to Vᵢₙ+Lpar*dᵢ/dₜ as shown in FIG. 2. The overshoot ends at time t2 when the input current drops to zero.

As described above, the voltage overshoot occurs at the time when the high side FET 108 is turned off and the low side FET 110 is to be turned on. Controller 104 can raise the gate voltage of the low side FET 110 using the voltage overshoot when turning on the low side FET 110, which can reduce the RDS_ON of the low side FET 110 and the resulting conduction loss. Further, by leveraging the voltage overshoot, the energy stored in the parasitic inductance Lpar can be recycled to charge the gate of the low side FET 110 instead of being dissipated and wasted. All these can improve the overall efficiency of the power converter 100.

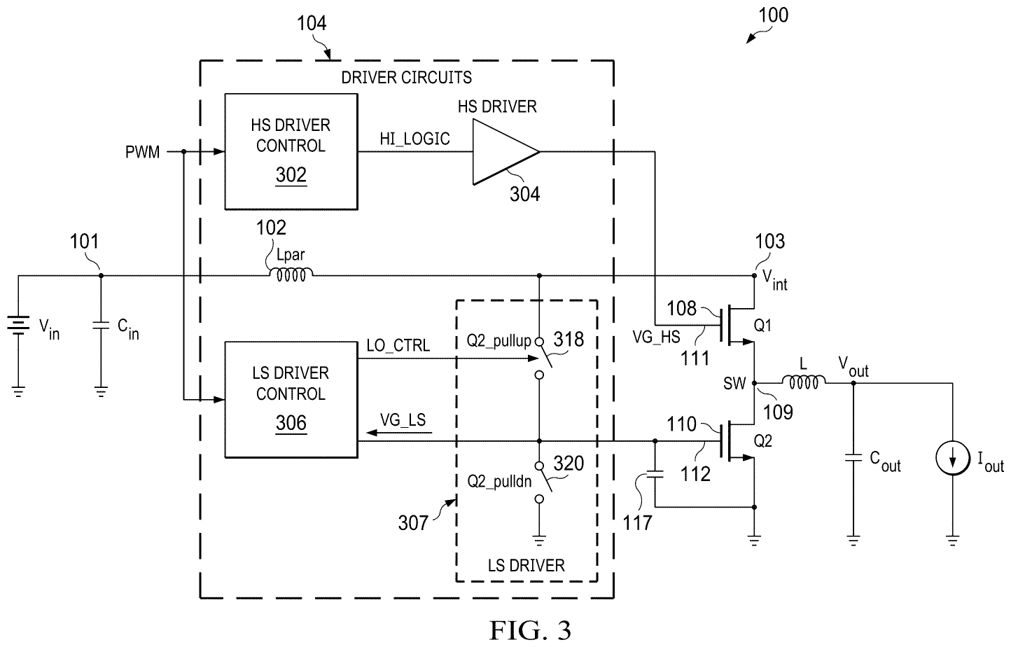

FIG. 3 illustrates examples of internal components of the controller 104 that can raise the gate voltage of the low side FET 110 using the overshoot of Vᵢₙₜ. As shown in the example of FIG. 3, the driver circuit 104 includes a high side (HS) driver control circuit 302, a high side driver 304, a low side (LS) driver control circuit 306, and a low side driver 307. The low side driver 307 further includes a pull-up driver circuit 318 (also labelled Q2_pullup) and a pull-down driver circuit 320 (also labelled Q2_pulldn) to set the gate voltage VG_LS of the low side FET 110, respectively. As shown in FIG. 3, the pull-up driver circuit 318 has pull-up driver input and is coupled between the input power terminal 103 and the gate/control terminal 112 of the low side FET 110. The pull-down driver circuit 320 having a pull-down driver input is coupled between the gate 112 of the low side FET 110 and the ground terminal. In one example, an external control signal, e.g., a pulse width modulation (PWM) signal, is provided as an input to both the high side driver control circuit 302 and the low side driver control circuit 306 to control their operations. The duty cycle of the PWM signal can set the relative durations of turning on of the high side FET 108 and the low side FET 110 in each cycle to set the Vout voltage. For example, the high side driver control circuit 302 can provide a control signal HI_logic to the high side driver 304 based on the PWM signal from the controller 105, and the high side driver 304 can set the voltage of the gate/control terminal 111 of the high side FET 108 (also labelled VG_HS) to turn it on/off based on the state of the HI_logic control signal. Also, the low side driver control circuit 306 can provide a control signal LO_CTRL to control the pull-up driver circuit 318. The low side driver control circuit 306 also provides a control signal (not shown in FIG. 3) to control the pull-down driver circuit 320. The pull-up driver circuit 318 and the pull-down driver circuit 320 can set the voltage of the gate/control terminal 112 of the low side FET 110 (VG_LS) based on the control signals from the low side driver control circuit 306. As to be described below, the low side driver control circuit 306 can set the state of the control signals (e.g., LO_CTRL) based on the PWM signal and/or a voltage at the switching terminal 109.

As shown, responsive to a state of the PWM signal indicating that the low side FET 110 is to be enabled, low side driver control circuit 306 can enable the pull-up driver circuit 318 and disable the pull-down driver circuit 320 to pull the gate/control terminal 112 of the low side FET 110 to the Vᵢₙₜ voltage. As the Vᵢₙₜ voltage overshoots, the gate voltage of the low side FET 110 also increases, which reduces the RDS_ON of the low side FET 112. Also, the low side driver control circuit 306 can sense the gate voltage of the low side FET 110 and disable the pull-up driver circuit 318 responsive to the gate voltage exceeding a threshold, to avoid applying an excessive gate voltage that may otherwise damage the low side FET 110.

In one example, the gate capacitance at the gate 112 of the low side FET 110 may operate as a sampling capacitor 117 to sample and detect the overshoot of the voltage VG_LS at the gate 112 of the low side FET 110. In one example, the pull-down driver circuit 120 of the low side FET 110 may operate as a sampling switch, which stops the sampling capacitor 117 from sampling when the gate voltage VG_LS of the low side FET 110 reaches or exceeds the threshold. In one example, the threshold can be set based on a gate voltage limit of the low side FET 110 in order to reduce voltage stress and maintain gate oxide integrity of the low side FET 110.

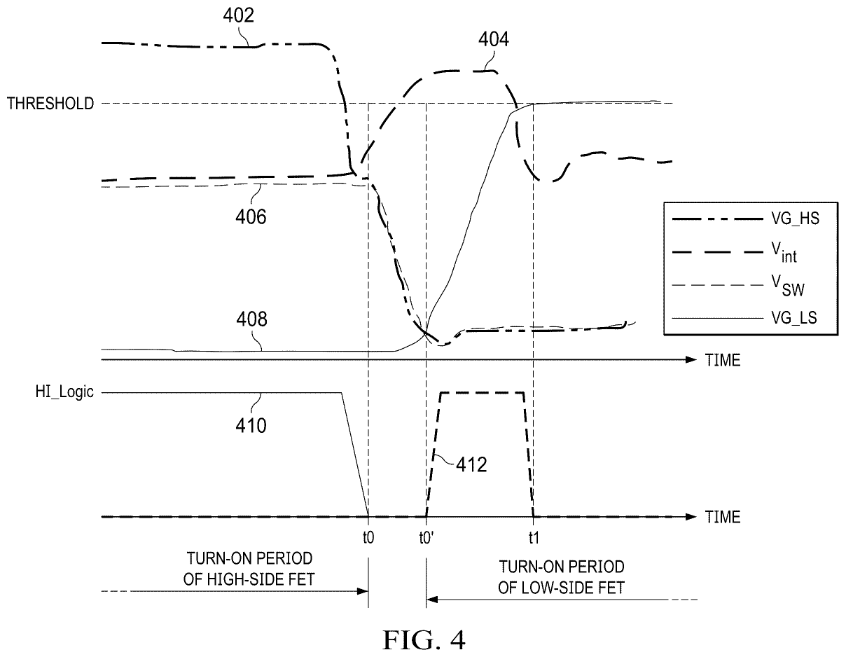

FIG. 4 includes graphs illustrating examples of operations of the power converter 104 including the components shown in FIG. 3. FIG. 4 includes graphs 402, 404, 406, 408, 410, and 412. Graph 402 represents an example variation of the gate voltage of the high side FET 108, also labelled VG_HS, with time. Graph 404 represents an example variation of the voltage at input power terminal 103 (Vᵢₙₜ) with time. Graph 408 represents an example variation of the voltage at the switching node 109 (V_{SW}) with time. Graph 408 represents an example variation of the gate voltage of the low side FET 110 with time. Graph 410 represents an example variation of the control signal HI_logic with time. Graph 412 represents an example variation of the control signal LO_CTRL with time.

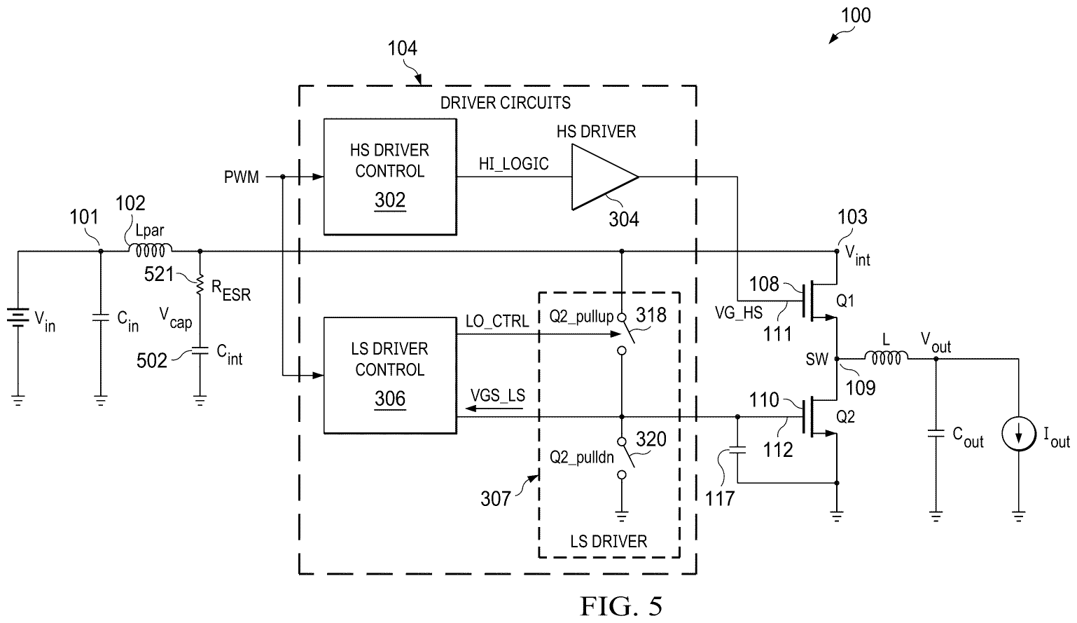

Referring to FIG. 5, before time t0, the HI_logic signal is in a logical high state, and the high side driver control circuit 302 provides VG_HS is at a high voltage to turn on the high side FET 108. With the high side FET 108 turned on, the input power terminal 103 and the switching node 109 can be electrically connected, and V_{SW} is almost equal to (or at least tracks) Vᵢₙₜ.

At time t0, responsive to the PWM signal indicating the end of the turn-on period of the high side FET 108 and the start of the turn-on period of the low side FET 110, the high side driver control circuit 302 sets the HI_logic signal from the logical high state to a logical low state, and reduces VG_HS. As VG_HS reduces to become equal to the switching node voltage V_{SW}, the gate-source voltage of the high side FET 108 is close to zero, and the high side FET 108 is turned off. The overshoot of Vᵢₙₜ starts at t0.

Also, after t0 (e.g., at t0′), responsive to the PWM signal indicating the start of the turn-on period of the low side FET 110, the low side driver control circuit 306 provides the LO_CTRL signal having a first state (e.g., a logical high state) to enable the pull-up driver circuit 318. As the pull-up driver circuit 318 is enabled, the gate voltage of the low side FET 110 rises. The low side FET 110 can be partially turned on after t0 and brings V_{SW} to zero. The high side driver control circuit 302 can set VG_HS to be equal to V_{SW} to disable the high side FET 108, and VG_HS also drops to zero.

The low side driver control circuit 306 can maintain the LO_CTRL signal at the first state until time t1 when the gate voltage of the low side FET 110 reaches a threshold, and the low side driver control circuit 306 sets the LO_CTRL signal to a second state (e.g., a logical low state) to disable the pull-up driver circuit 318. With the pull-up driver circuit 318 disabled, the gate of the low side FET 110 can become floating, and the gate voltage of the low side FET 110 can stay at close to the threshold voltage. The low side FET 110 is fully turned on at time t1, and the RDS_ON of the low side FET 110 is reduced due to the elevated gate voltage.

In FIG. 4, the low side driver control circuit 306 sets the LO_CTRL signal at the first state (and enables pull-up driver circuit 318) at around the same time of the overshoot of Vᵢₙₜ (e.g., between times t0 and t1), to allow the overshoot to elevate the gate voltage of the low side FET 110. Such an arrangement may require the low side driver control circuit 306 to align the LO_CTRL signal with the overshoot voltage, and misalignment between the LO_CTRL signal and the overshoot voltage may reduce the amount of time provided for the pull-up driver circuit to pull up the gate voltage of the low side FET 110 towards the overshoot voltage. The low side driver control circuit 306 and the pull-up driver circuit 318 may each have a high bandwidth and a high timing precision to achieve the alignment.

FIG. 5 illustrates an example of power converter 100 including components that can relax the required alignment between the LO_CTRL signal and the overshoot voltage. As shown in FIG. 5, the power converter 100 includes a capacitor 502 (also labelled Cᵢₙₜ) coupled between the input power terminal 103 and the ground terminal (with the rest of the components operating the same as discussed above). In some examples, capacitor 502 can be implemented on the same semiconductor die, or at least integrated within the same integrated circuit package, as the high side FET 108 and the low side FET 110, to reduce the parasitic inductance between the capacitor and the input power terminal 103. In some examples, capacitor 502 can be a trench capacitor or an capacitor integrated on a semiconductor die, such as described in, for example, U.S. Pat. No. 11,081,955, titled “UNIDIRECTIONAL RING MITIGATION IN A VOLTAGE CONVERTER”; U.S. Pat. No. 10,559,650, titled “TRENCH CAPACITOR WITH WARPAGE REDUCTION”; U.S. Pat. No. 10,622,073, titled “INTEGRATED CIRCUIT INCLUDING VERTICAL CAPACITORS”; U.S. Pat. No. 11,222,986, titled “A SEMICONDUCTOR DEVICE WITH AN INTEGRATED DEEP TRENCH CAPACITOR HAVING HIGH CAPACITANCE DENSITY AND LOW EQUIVALENT SERIES RESISTANCE”; and U.S. patent application Ser. No. 18/498,811, titled “INTEGRATED DEEP TRENCH CAPACITOR HAVING HIGH CAPACITANCE DENSITY AND VOLTAGE LINEARITY”, filed on Oct. 31, 2023, all of which are incorporated herein by reference. FIG. 5 also shows a parasitic equivalent series resistance 521 (also labelled R_{ESR}) between the input power terminal 103 and the capacitor 502. The voltage between Cᵢₙₜ and R_{ES} is labelled V_{cap}.

In one example, the energy stored in Lpar 102 can be transferred to the integrated capacitor 502, and charge the integrated capacitor 502 to the V_{cap} voltage, which is higher than Vᵢₙₜ. The integrated capacitor 502 can then be discharged later through the pull-up driver circuit to pull up the gate voltage of the low side FET 110 to the V_{cap} voltage. Such arrangements can relax the alignment requirement between the LO_CTRL signal and the overshoot voltage, as well as the required bandwidth and timing precisions of the low side driver control circuit 306 and the pull-up driver circuit 318.

The integrated capacitor 502 can provide other advantages. For example, transferring the energy from the Lpar 102 to the capacitor 502 can avoid the energy being dissipated. According, the capacitor 502 reduces the effective energy loss during this transition. The Capacitor 502 can also reduce the magnitude of Vᵢₙₜ overshoot at internal power node 103 by dissipating some of the energy in the Lpar 102 to reduce voltage stress on the high side FET 108.

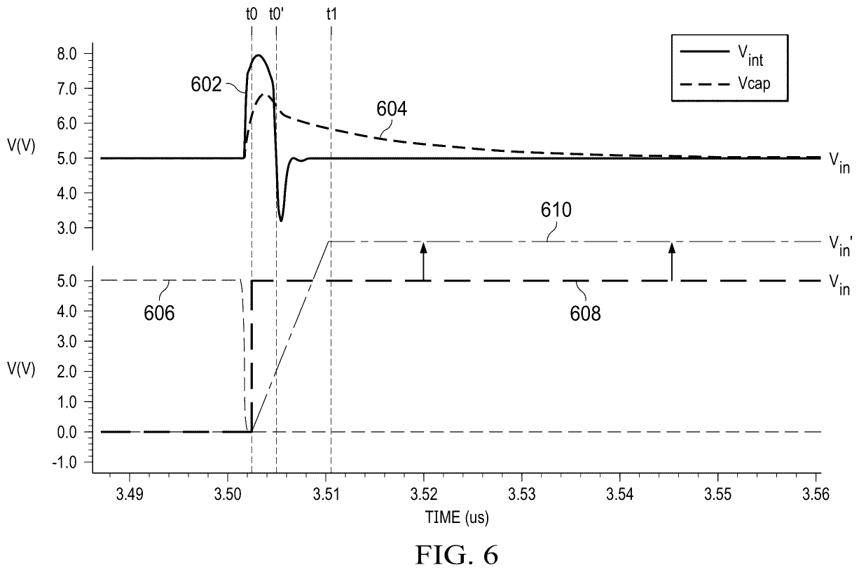

FIG. 6 includes graphs illustrating examples of operations of the power converter 104 including the integrated capacitor 502. FIG. 6 includes graphs 602, 604, 606, and 608. Graph 602 represents an example variation of the voltage at input power terminal 103 (Vᵢₙₜ) with time. Graph 604 represents an example variation of the V_{cap} voltage at the integrated capacitor 502 with time. Graph 606 represents an example variation of the control signal HI_logic with time. Graph 608 represents an example variation of the control signal LO_CTRL with time. Graph 610 represents an example variation of the gate voltage of the low side FET 110 (VG_LS) with time.

At time t0, responsive to the PWM signal indicating the end of the turn-on period of the high side FET 108 and the start of the turn-on period of the low side FET 110, the high side driver control circuit 302 changes the HI_logic signal from the logical high state to a logical low state. Also, after some delay from time t0, the low side driver control circuit 306 provides the LO_CTRL signal having a first state (e.g., a logical high state) to enable the pull-up driver circuit 318 to pull the gate voltage of the low side FET 110 towards the V_{cap} voltage.

Also, the voltage overshoot, shown in graph 602, starts from Vᵢₙ at time t0 and drops back to Vᵢₙ at time t0′. This provides a short time window for the pull-up driver circuit 318 to pull the gate voltage. Instead, the energy of the voltage overshoot is transferred to capacitor 502, which discharges through R_{ESR} and maintain the voltage V_{cap} at a higher voltage than Vᵢₙ beyond t0′. This allows the gate voltage of the low side FET 110 to continue pulling up the gate voltage of the low side FET 110 to an elevated voltage Vᵢₙ′, which is above Vᵢₙ, to reduce the RDS_ON of the low side FET 110. The low side driver control circuit 306 can set the LO_CTRL signal back to the second state and disable the pull-up driver circuit 318 at time t1, after the voltage overshoot goes below Vᵢₙ at t0′, when the gate voltage of the low side FET 110 exceeds a threshold voltage, and the gate voltage stays at the elevated level Vᵢₙ′ after t1.

Responsive to the HI_logic signal, the high side driver 304 reduces VG_HS. As VG_HS reduces to become equal to the switching node voltage V_{SW}, the gate-source voltage of the high side FET 108 is close to zero, and the high side FET 108 is turned off.

Also, after t0, the turn-on period of the low side FET 110 starts, and the low side driver control circuit 306 provides the LO_CTRL signal having a first state (e.g., a logical high state) to enable the pull-up driver circuit 318. As the pull-up driver circuit 318 is enabled, the gate voltage of the low side FET 110 rises. The low side FET 110 can be partially turned on after t0 and brings V_{SW} to zero. The high side driver control circuit 302 can set VG_HS to be equal to V_{SW} to disable the high side FET 108, and VG_HS also drops to zero.

The low side driver control circuit 306 can maintain the LO_CTRL signal at the first state until time t1 when the gate voltage of the low side FET 110 reaches a threshold, and the low side driver control circuit 306 sets the LO_CTRL signal to a second state (e.g., a logical low state) to disable the pull-up driver circuit 318. With the pull-up driver circuit 318 disabled, the gate of the low side FET 110 can become floating and the gate voltage of the low side FET 110 can stay at close to the threshold voltage. The low side FET 110 is fully turned on at time t1, and the RDS_ON of the low side FET 110 is reduced due to the elevated gate voltage.

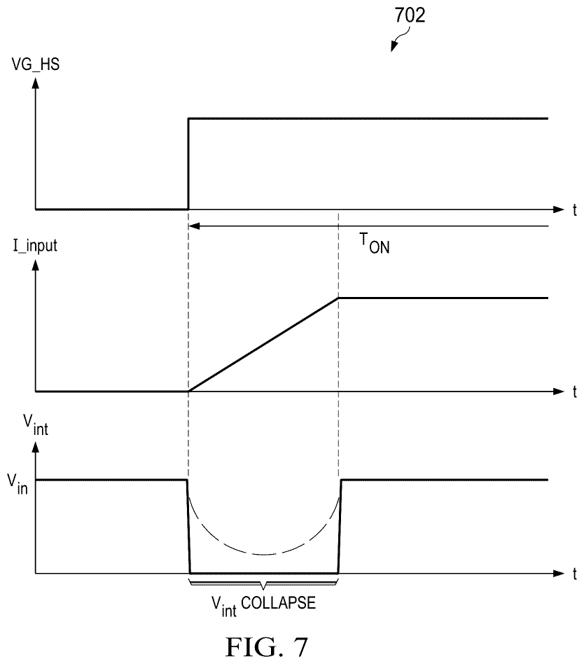

While the addition of the integrated capacitor 502 is beneficial in reducing switching loss during the turning off of the high side FET 108 and extending the time provided to the pull-up driver circuit 318 for pulling up the gate voltage of the low side FET 110, the integrated capacitor 502 may also increase switching loss during the turning off of the high side FET 108. FIG. 7 includes graphs 702, 704, and 706 illustrating examples of operations of the power converter 104 including the integrated capacitor 502. Graph 702 represents an example variation of the VG_HS voltage of the high side FET 108 with time, graph 704 represents illustrates an example variation of the input current (supplied by an external source that provides the external voltage Vᵢₙ) with time. Graph 706 illustrates an example variation of the internal node voltage Vᵢₙₜ at an input/internal power node/terminal 103 with respect to time.

At time t0, the VG_HS voltage transitions to a high voltage state to turn on the high side FET 108, and the input current increases with time between times t0 and t1. During that interval, without the integrated capacitor 502, the Vᵢₙₜ voltage can drop to zero since the parasitic inductance (Lpar) 102 acts against the change in the current flowing through it. Having the Vᵢₙₜ voltage drop to zero during the VG_HS transition can provide zero voltage switching and reduces the switching loss incurred by the high side FET 108. But the integrated capacitor 502 is also charged to Vᵢₙ at steady state. Between t0 and t1, as the Vᵢₙₜ voltage drops, the capacitor 502 can discharge to raise the collapsing Vᵢₙₜ node voltage back to Vᵢₙ. Accordingly, during the transition of the VG_HS voltage, the Vᵢₙₜ voltage may be non-zero, which increases the switching loss of the high side FET 108.

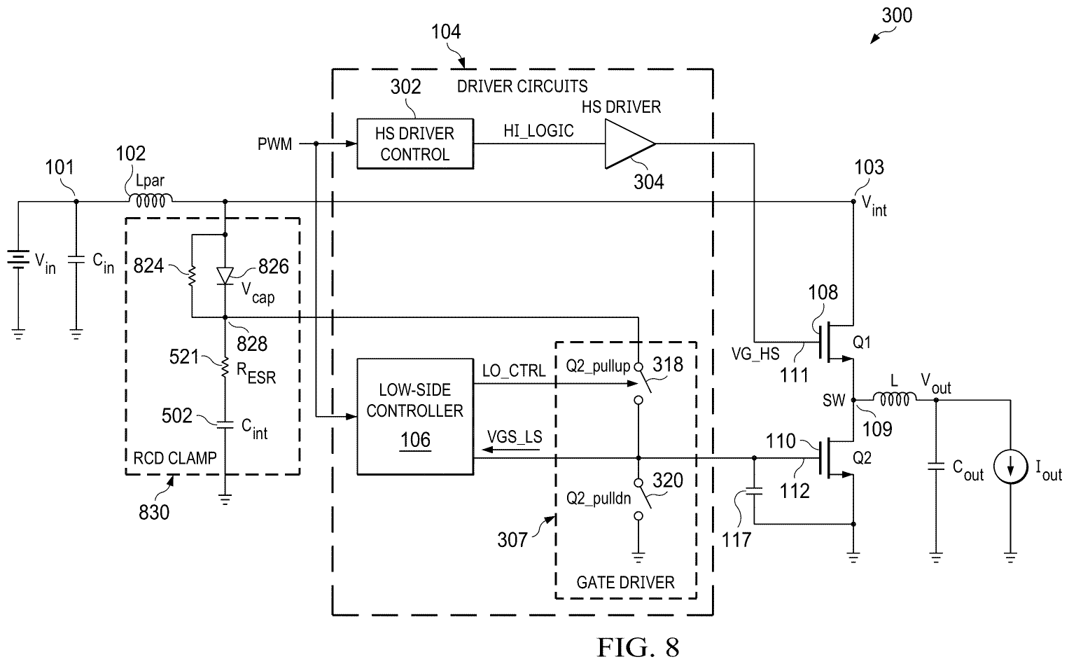

FIG. 8 illustrates an example of power converter 100 that can address at least some of the issues described above. As shown in FIG. 8, the power converter 100 can include a resistor 824 and a diode 826 coupled between the internal power node 103 and the integrated capacitor 502, where the anode of diode 826 is coupled to the internal power node 103 and the cathode of diode 826 (labelled 828) is coupled to the integrated capacitor 502. In some examples, the resistor 824, the diode 826, and the integrated capacitor 502 can form a resistor-capacitor-diode (RCD) clamp 830. The cathode 828 of the diode 826 is coupled to the pull-up driver 118 and provides the V_{cap} voltage.

During the turning-off of the high side FET 108, as the Vᵢₙₜ voltage overshoots and exceeds the V_{cap} voltage, the diode 826 can be forward biased and connect the integrated capacitor 502 to the internal power node 103, and the integrated capacitor 502 can be charged using the energy of the overshoot. The integrated capacitor 502 can also discharge and provide the V_{cap} voltage for the turning-on of the low side FET 110, as described above.

Also, during the turning-on of the high side FET 108, the Vᵢₙₜ voltage collapses to zero. The diode 826 can be reverse biased and disconnect the integrated capacitor 502 from the internal power node 103, which can prevent the integrated capacitor 502 from discharging and raising the Vᵢₙₜ voltage at the internal power terminal 103, to allow zero voltage switching of the high side FET 108.

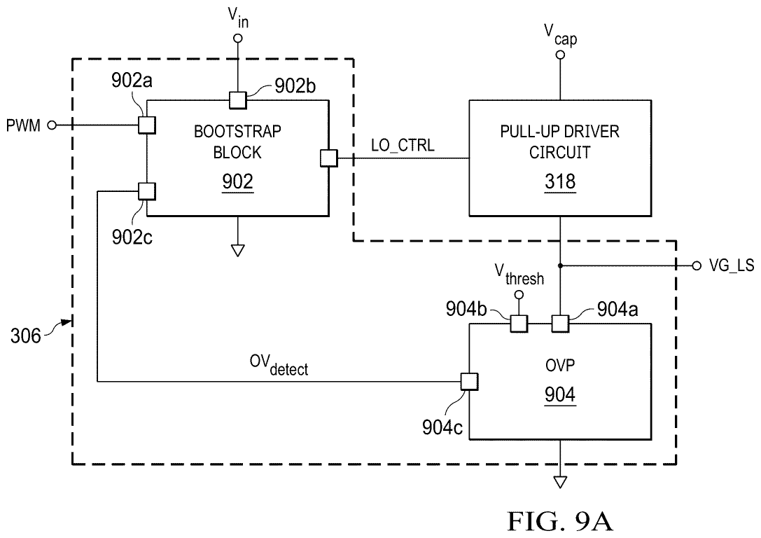

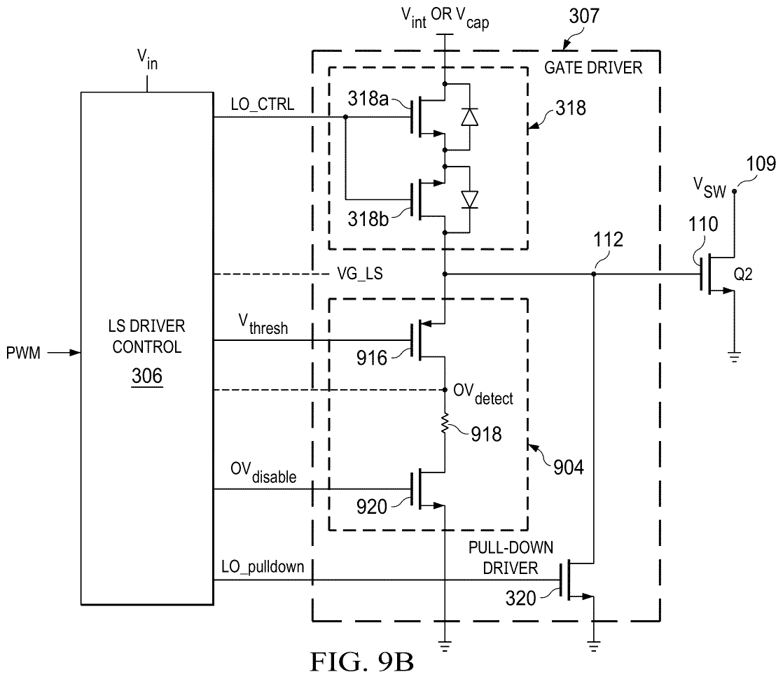

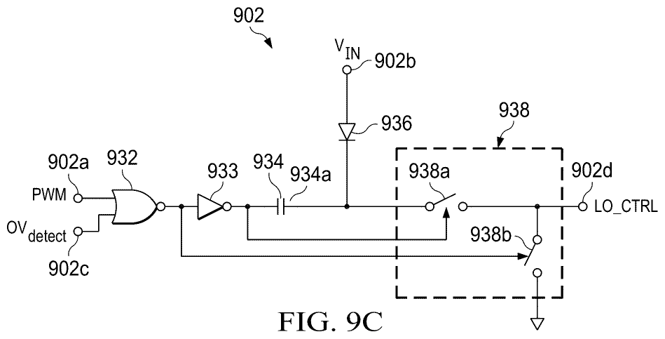

FIG. 9A, FIG. 9B, and FIG. 9C illustrate examples of internal components of the low side driver control circuit 306 and low side driver circuit 307. Referring to FIG. 9A, low side driver control circuit 306 includes a bootstrap block 902 and an overvoltage protection (OVP) circuit 904. Bootstrap block has a first input 902a, a second input 902b, a third input 902c, and an output 902c. In some examples, the first input 902a is coupled to the switching terminal 109 to receive the V_{SW} voltage. In some examples, the first input 902a is coupled to the controller 105 to receive the PWM signal. The second input 902b is coupled to external power terminal 101 to receive the Vᵢₙ voltage. The output 902d is coupled to the pull-up driver circuit 318 to provide the LO_CTRL control signal.

Also, the overvoltage protection circuit 904 has a first input 904a, a second input 904b, and an output 904c. The first input 904a is coupled to the gate 112 of the low side FET 110 to receive the VG_LS voltage. The second input 904a receives a threshold voltage Vₜₕᵣₑₛₕ which sets an upper limit of the VG_LS voltage. In some examples, Vₜₕᵣₑₛₕ can represent a voltage limit for gate oxide integrity of the low side FET 110. The output 904c is coupled to the third input 902c of the bootstrap block to provide an overvoltage detection signal (OV_{detect}). Specifically, the overvoltage protection circuit 904 can constantly/continuously monitor the gate voltage VG_LS of the low side FET 110 so that it does not exceed a pre-determined safe voltage limit/threshold Vₜₕᵣₑₛₕ. If the gate voltage VG_LS of the low side FET 110 exceeds the voltage threshold Vₜₕᵣₑₛₕ, the overvoltage protection circuit 904 can assert the over-voltage detection signal OV_{detect} which can cause the bootstrap block 902 to change the state of the LO_CTRL signal to turn off the pull-up driver 118.

In one example, the bootstrap block 902 of the low side driver control circuit 306 can receive the PWM signal and the over-voltage detection signal OV_{detect}, and provide the LO_CTRL signal based on the state of the PWM signal and the state of over-voltage detection signal OV_{detect}. The bootstrap block 902 can also receive a high voltage, such as the Vᵢₙ voltage at the external power terminal 101 (as shown in FIGS. 9A-9C), the internal node voltage Vᵢₙₜ at an input/internal power node/terminal 103, or the V_{cap} voltage from the RCD clamp 830, and the bootstrap block 902 can provide the LO_CTRL signal in the asserted state by bootstrapping the high voltage.

FIG. 9B illustrates examples of internal components of bootstrap block 902, which includes a logic gate 932 (e.g., a OR gate shown in FIG. 9B), an inverter 933, a capacitor 934, a diode 936, switches 938, and a switch control circuit 940. The logic gate 932 have inputs coupled to inputs 902a and 902c to receive, respectively, the PWM signal and the OV_{detect} signal. The logic gate 932 output can be at a logic high state if PWM is in the high state (indicating that the low side FET 110 is to be turned off) or OV_{detect} is high (indicating the VG_LS is above the threshold), and the pull-up driver circuit 318 is to be turned off in either case. The logic gate 932 output can be at a logic low state if both the PWM is in the low state (indicating that the low side FET 110 is to be turned on) and OV_{detect} is low (indicating the VG_LS is below the threshold), and the pull-up driver circuit 381 can be turned on.

Also, the inverter 933 is coupled between the output of the logic gate 832 and the capacitor 934, and the capacitor 934 is coupled between the output of the inverter 933 and the diode 936. The diode 936 is coupled between the external power terminal 101 and a plate 934a of the capacitor 934. When the output of the inverter 933 is in a logic low state (e.g., at OV), the capacitor 934 can store a voltage difference of Vᵢₙ (or one of Vᵢₙₜ or V_{cap}). When the output of the inverter 933 is in a high logic state (e.g., a supply voltage V_{cc} of the inverter 933), the capacitor 934 can set the voltage of plate 934a to a sum of V_{cc}+Vᵢₙ (or one of V_{cc}+Vᵢₙₜ or V_{cc}+V_{cap}), thereby bootstrapping the voltage.

Switches 938 are controlled by logic gate 932 and inverter 934. Switches 938 includes a switch 938a coupled between the diode 936 (and plate 934a) and the output 902d, and a switch 938b coupled between the output 902d and ground. If the logic gate 932 output is at the logic high state to turn off the pull-up driver circuit 381, the switch 938b can be enabled, and the switch 938a can be disabled, to connect the output 902d to the ground to provide a ground voltage as the LO_CTRL signal. Also, if the logic gate 932 output is at the logic low state to turn on the pull-up driver circuit 381, the switch 938b can be disabled, and the switch 938a can be enabled, to connect the output 902d to the plate 934a to provide the bootstrapped voltage as the LO_CTRL signal. With such arrangements, when the LO_CTRL signal is at the logic high state, the bootstrap block 902 can provide the LO_CTRL signal at a voltage higher than Vᵢₙ to ensure that the pull-up driver circuit 318 is fully enabled to pull VG_LS to the V_{cap} voltage. Also, when the LO_CTRL signal is at the logic low state, the bootstrap block 902 can provide the LO_CTRL signal at the ground voltage to ensure that the pull-up driver circuit 318 is disabled.

FIG. 9C illustrates additional examples of internal components of the low side driver control circuit 306 and low side driver circuit 307. Referring to FIG. 9c, the pull-up driver circuit 318 includes a pair of transistors 130/132 (e.g., N-type FETs or NFETs) with back-to-back diodes. The back-to-back diodes allow the pull-up driver circuits to operate as a bi-directional switch to block voltage in both directions, including when VG_LS exceeds Vᵢₙ. The pull-down driver 320 is also coupled to the low side driver control circuit 306 and can be enabled by a LO_pulldown signal. The low side driver control circuit 306 can enable the pull-down driver 320 responsive to, for example, the PWM signal indicating that the low side FET 110 is to be turned off.

Also, the overvoltage protection circuit 904 includes a transistor 916, a resistor 918, and a transistor 920. Transistor 916 have a control terminal coupled to the input 904b to receive the threshold voltage Vₜₕᵣₑₛₕ, a first current terminal coupled to the gate 112 of the low side FET 110 to receive the VG_LS voltage, and a second current terminal coupled to the output 904c to provide the overvoltage detection signal OV_{detect}. Transistor 916 can operate as a comparator to compare between VG_LS and Vₜₕᵣₑₛₕ. If VG_LS exceeds Vₜₕᵣₑₛₕ, transistor 916 can be turned on and pull up the voltage of OV_{detect}. Transistor 920 can receive an OV_{disable} signal from the low side driver control circuit 306, which can assert the OV_{disable} signal to disable the overvoltage protection circuit after the OV_{detect} signal is asserted and the pull-up driver 320 is disabled, to reduce the quiescent current through transistor 916.

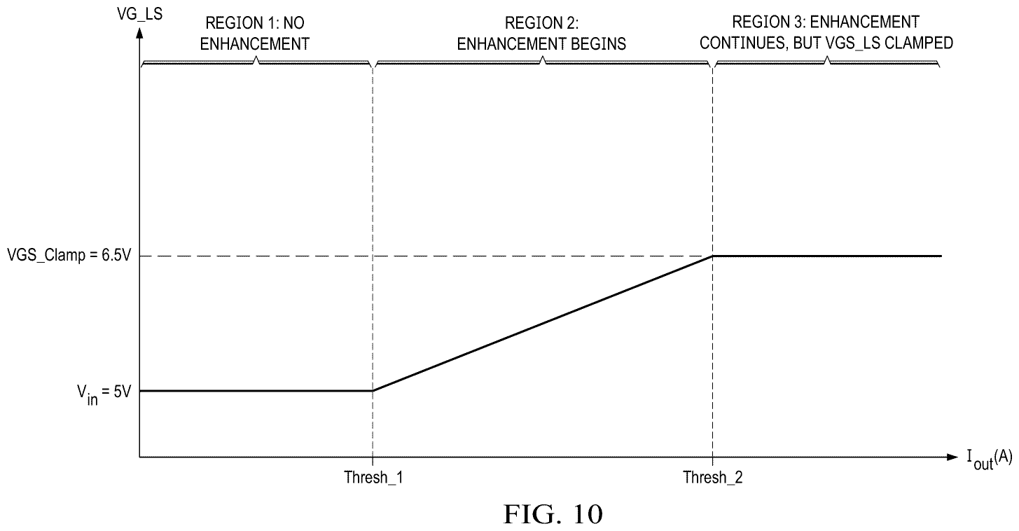

FIG. 10 depicts an example of VG_LS values across load current Iₒᵤₜ of the low side FET 110 as controlled by the gate driver 107 discussed above. The excess energy in Lpar 102 and capacitor 502 is the basis for allowing the gate driver 107 to reduce the RDS_ON of the low side FET 110. The magnitude of this energy depends on factors such as the output load current Iₒᵤₜ, value of Cᵢₙₜ, value of Lpar, etc. Thus, depending on the operating condition of the converter, the gate driver 107 also operates in different regions as discussed below:

Region 1: when Iₒᵤₜ<Thresh_1, the energy available from Lpar is too little to provide any enhancement, and the VG_LS remains limited to Vᵢₙ, which is the typical operating region for power converters. In one example, two thresholds Thresh_1 and Thresh_2 can be defined:

Thresh_1=Qg/√(0.5*Lpar*Cint)

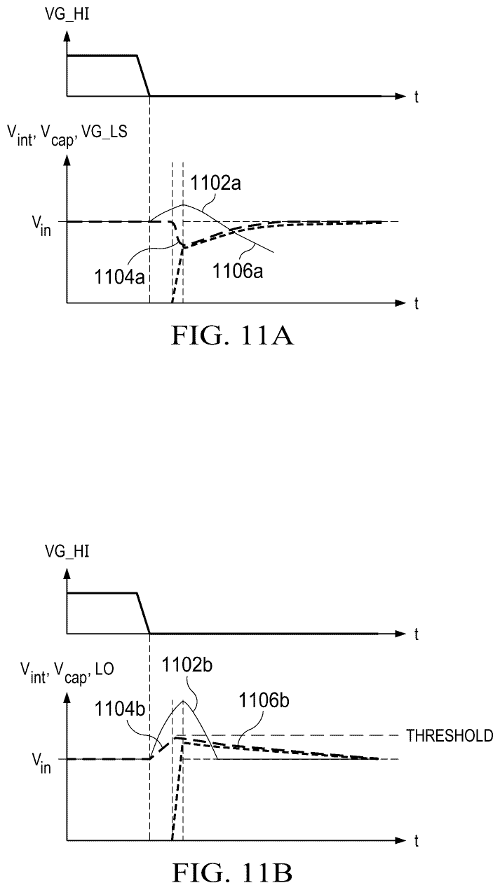

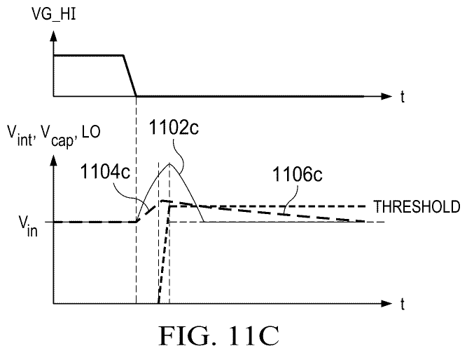

Thresh_2=Thresh_1+(VGS_LS_Clamp−Vin)*√(C int/(0.5*Lpar))

wherein Qg is the fate charge of the low side FET 110 and VGS_Clamp is the maximum limit of the VG_LS voltage for the low side FET 110 (same as the voltage threshold Vₜₕᵣₑₛₕ).
Region 2: when Iₒᵤₜ>Thresh_1, there is sufficient energy present in Lpar or Cᵢₙₜ now to meet the gate charge requirement for turning on the low side FET 110. There is also sufficient voltage overshoot of Vᵢₙₜ or V_{cap}, which allows VG_LS to be raised about Vᵢₙ, thereby providing RDS_ON enhancement. The overshoot is directly proportional to the load current Iₒᵤₜ, thereby increases linearly as Iₒᵤₜ increases. However, this overshoot is not so large that the maximum VG_LS limit of the low side FET 110Vₜₕᵣₑₛₕ would be hit. Thus, no need of VG_LS clamping in this region.
Region 3: when Iₒᵤₜ>Thresh_2, the available voltage overshoot gets too big, and too close to the maximum VGS limit of the low side FET 110. Thus, the VG_LS of the low side FET 110 needs to be clamped to a certain limit VGS_Clamp (chosen to be 6.5V in the example of FIG. 11). Beyond this point, which defines the lowest attainable RDS_ON value, increasing Iₒᵤₜ does not further increase the VG_LS value like in Region 2, as a result of the clamping action.

FIGS. 11A, 11B, and 11C include graph that illustrate example operations of pull-up driver circuit 318 in different regions of FIG. 10. In FIG. 11A, graph 1102a represents an example variation of Vint with time, graph 1104a represents an example variation of V_{cap} with time, and graph 1106a represents an example variation of VG_LS with time. Also, in FIG. 11B, graph 1102b represents an example variation of Vint with time, graph 1104b represents an example variation of V_{cap} with time, and graph 1106b represents an example variation of VG_LS with time. Further, in FIG. 11C, graph 1102c represents an example variation of Vint with time, graph 1104c represents an example variation of V_{cap} with time, and graph 1106c represents an example variation of VG_LS with time.

FIG. 11A illustrates example operations of pull-up driver circuit 318 in region 1 of FIG. 10. Because Iₒᵤₜ<Thresh_1, there is no overshoot in the V_{cap} voltage, and because the overcurrent protection circuit 904 is not triggered, the pull-up driver circuit 318 is enabled throughout the on-time of the low side FET 110, and the VG_LS voltage tracks the V_{cap} voltage and does not rise above Vin.

FIG. 11B illustrates example operations of pull-up driver circuit 318 in region 2 of FIG. 10. In region 2, Iₒᵤₜ>Thresh_1, and V_{cap} also overshoots above Vin. But there is insufficient energy provided to the pull-up driver circuit 318 to raise the VG_LS voltage above the threshold voltage. Therefore, the overcurrent protection circuit 904 is not triggered, the pull-up driver circuit 318 is enabled throughout the on-time of the low side FET 110, and the VG_LS voltage tracks the V_{cap} voltage and falls with the V_{cap} voltage as Cᵢₙₜ discharges.

FIG. 11C illustrates example operations of pull-up driver circuit 318 in region 3 of FIG. 10. In region 3, Iₒᵤₜ>Thresh_2, and V_{cap} overshoots above Vin. There is sufficient energy provided to the pull-up driver circuit 318 to raise the VG_LS voltage above the threshold voltage. When this happens, the overcurrent protection circuit 904 is triggered, the pull-up driver circuit 318 is disabled, and the VG_LS voltage stays at an elevated level and does not track V_{cap}.

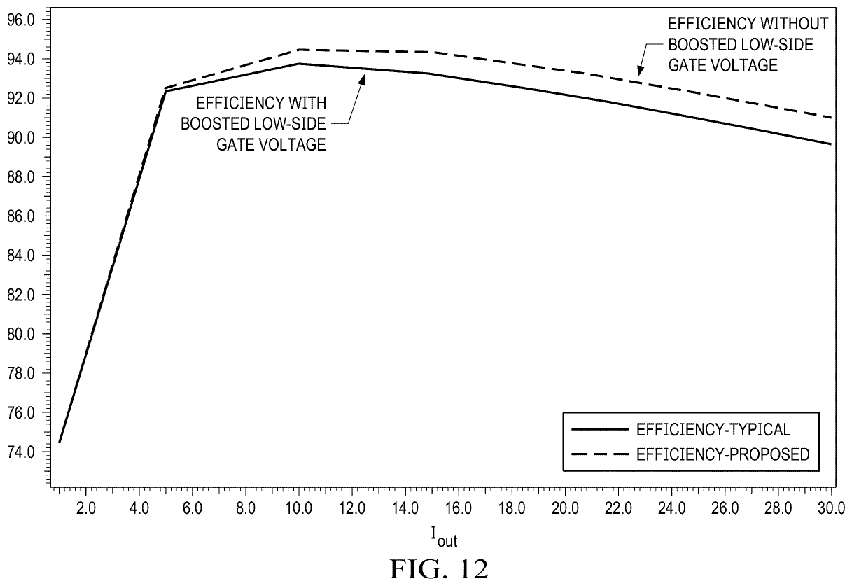

FIG. 12 depicts an example of comparison of efficiency across load currents without and with overshoot sampling, respectively, when Vᵢₙ=5V, Lpar=500 pH, and Cᵢₙₜ=8 nF. As shown by the example of FIG. 12, the proposed converter discussed above enables increased efficiency at higher load current Iₒᵤₜ even with lower Vᵢₙ due to the overshoots caused by the parasitic inductance (Lpar) 102, thus removing dependence of the conduction loss on Vᵢₙ at higher load current Iₒᵤₜ. The proposed converter reduces RDS_ON of the low side FET 110, and hence conduction losses, without increasing FET size. Since the gate charge for turning on the low side FET 110 is supplied by the energy present in the Lpar 102, gate charge loss is saved.

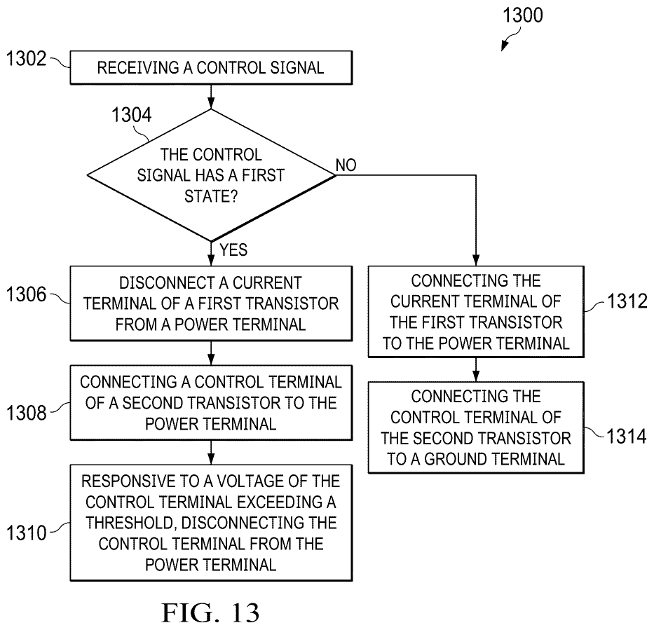

FIG. 13 is a flowchart of a method 1300 for controlling a power converter. The method 1300 can be performed by one or more of various components of power converters discussed above.

The method 1300 starts at block 1302, where a control signal (e.g., the PWM signal, the VSW signal, etc.) is received. If the control signal has a first state (block 1304), the method 1300 continues to block 1306, where a current terminal of a first transistor (e.g., the high side FET 108) is disconnected from a power terminal (e.g., external power terminal 101) that receives a first voltage Vin. The method 1300 continues to block 1308, where a control terminal of a second transistor (e.g., the low side FET 110) is connected to the power terminal. As described above, due to the voltage overshoot from the energy stored in the parasitic inductance Lpar, the control terminal voltage of the second transistor can be increased to a second voltage Vin′ above the Vin voltage at the power terminal to reduce the RDS_ON of the second transistor, which can reduce the conduction loss. The control terminal can be connected directly to the power terminal or indirectly via, for example, resistor 824, where capacitor 502 can discharge some of the stored energy from Lpar. Also, at block 1310, responsive to a voltage of the control terminal exceeding a threshold, the control terminal is disconnected from the power terminal, to avoid the control terminal voltage (VG_LS) exceeding a safe limit. The threshold can represent, for example, a voltage limit for gate oxide integrity of the second transistor.

Alternatively, if the control signal does not have a first state, the method 1300 continues to block 1312, where the current terminal of the first transistor (the high side FET 108) is connected to the power terminal. The method 1300 then continues to block 1314, where the control terminal of the second transistor (the low side FET 110) is grounded.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

In this description, unless otherwise stated, “about,” “approximately” or “substantially” preceding a parameter means being within +/−10 percent of that parameter or, if the parameter is zero, a reasonable range of values around zero.

Modifications are possible in the described embodiments, and other embodiments are possible, within the scope of the claims.

What is claimed is:

1. An apparatus comprising:
a first transistor coupled between a power terminal and a switching terminal, the first transistor having a first transistor control terminal;
a second transistor coupled between the switching terminal and a ground terminal, the second transistor having a second transistor control terminal;
a first switch coupled between the power terminal and the second transistor control terminal, the first switch having a first switch control terminal;
a second switch coupled between the second transistor control terminal and the ground terminal, the second switch having a second switch control terminal; and
a controller having a control input, a first control output, and a second control output, the control input coupled to the second transistor control terminal, the first control output coupled to the first switch control terminal, and the second control output coupled to the second switch control terminal.

2. The apparatus of claim 1, wherein the first and second transistors and the first and second switches are on a semiconductor die, the power terminal is external to the semiconductor die, the apparatus is configured to receive a first voltage at the power terminal, and the second switch is configured to set the second switch control terminal to a second voltage higher than the first voltage.

3. The apparatus of claim 1, wherein the controller is configured to set a state of the first switch control terminal based on a voltage at the control input.

4. The apparatus of claim 3, wherein the controller is configured to:
responsive to the voltage being below a threshold, enable the first switch to connect the power terminal to the second transistor control terminal; and
responsive to the voltage being above the threshold, disable the first switch to disconnect the power terminal from the second transistor control terminal.

5. The apparatus of claim 4, wherein the threshold is set based on a voltage limit for gate oxide integrity of the second transistor.

6. The apparatus of claim 1, wherein the first switch includes a bi-directional switch.

7. The apparatus of claim 3, wherein the control input is a first control input, and the controller has a second control input;
wherein the controller is configured to, responsive the second control input having a first state, set a state of the first switch control terminal based on a voltage at the first control input.

8. The apparatus of claim 7, wherein the second control input is coupled to the switching terminal.

9. The apparatus of claim 7, wherein the controller is configured to, responsive to the second control input having the first state, disable the second switch to disconnect the second transistor control terminal from the ground terminal.

10. The apparatus of claim 8, wherein the controller is configured to, responsive to the second control input having a second state, enable the second switch to connect the second transistor control terminal to the ground terminal.

11. The apparatus of claim 9, wherein the controller is a first controller, and the apparatus further comprises a second controller having a third control input and a third control output, the third control input coupled to the second control input, the third control output coupled to the first transistor control terminal, the second controller configured to:
responsive the second control input having the first state, disable the first transistor;
responsive to the second control input having the second state, enable the second transistor.

12. The apparatus of claim 1, further comprising a capacitor having a first terminal and a second terminal, the first terminal coupled to the power terminal, and the second terminal coupled to the ground terminal,
wherein the first switch is coupled between the first terminal of the capacitor and the second transistor control terminal.

13. The apparatus of claim 12, wherein the capacitor, the first and second transistors, and the first and second switches are on a semiconductor die.

14. The apparatus of claim 13, wherein the capacitor is a trench capacitor.

15. The apparatus of claim 12, further comprising a first resistor and a diode coupled between the power terminal and the first terminal of the capacitor, and the first switch is coupled between the first terminal and the second transistor control terminal.

16. An apparatus comprising:
a capacitor having a first terminal and a second terminal, the second terminal coupled to a ground terminal;
a first switch coupled between the first terminal and a transistor control terminal, the first switch having a first switch control terminal;
a second switch coupled between the transistor control terminal and the ground terminal, the second switch having a second switch control terminal; and
a controller having a control input, a first control output, and a second control output, the control input coupled to the transistor control terminal, the first control output coupled to the first switch control terminal, and the second control output coupled to the second switch control terminal.

17. The apparatus of claim 16, further comprising:
a first transistor coupled between a power terminal and a switching terminal, the power terminal coupled to the first terminal; and
a second transistor coupled between the switching terminal and the ground terminal, the second transistor having the transistor control terminal coupled to the first and second switches.

18. The apparatus of claim 17, further comprising a resistor and a diode coupled between the power terminal and the first terminal.

19. A method, comprising:
receiving a control signal;
responsive to the control signal having a first state:
disconnecting a current terminal of a first transistor from a power terminal;
connecting a control terminal of a second transistor to the power terminal; and
responsive to a voltage of the control terminal exceeding a threshold, disconnecting the control terminal from the power terminal; and
responsive to the control signal having a second state:
connecting the current terminal to the power terminal; and
connecting the control terminal to a ground terminal.

20. The method of claim 19, further comprising:
setting the threshold based on a voltage limit for gate oxide integrity of the second transistor.
